(19) United States
(12) Patent Application Publication
(10) Pub. No.: US 2010/0040888 A1
(43) Pub. Date: Feb. 18, 2010

(54) Metallized barrier material

(75) Inventors: Thomas R. Fields, Millford, MA (US); Kurt B. Gundlach, Warren, MA (US)

Correspondence Address: THE WATSON INTELLECTUAL PROPERTY GROUP, PLC, 3133 HIGHLAND DRIVE, SUITE 200, HUDSONVILLE, MI, 49426, US

(73) Assignee: Vacumet Corp.

(21) Appl. No.: 12/583,049

(22) Filed: Aug. 13, 2009

Related U.S. Application Data
(60) Provisional application No. 61/188,947, filed on Aug. 13, 2008.
(60) Provisional application No. 61/268,469, filed on Jun. 12, 2009.

(51) Int. Cl. B32B 15/092; C23C 16/00; C23C 28/00

(52) U.S. Cl. 428/418; 427/250

(57) ABSTRACT

A metallized barrier material comprising a base material, a metallized layer and a protective coating. The base material has a first surface and a second surface. The metallized layer is vapor deposited on the first surface of the base material to a desired optical density. The protective coating is applied to the metallized layer, wherein the protective coating comprises a butyl methacrylate or a combination of an epoxy component and an acrylic component wherein the epoxy component has an EEW of less than 800.

### CROSS REFERENCE TO RELATED APPLICATION

This application claims priority from U.S. Provisional Patent App. Ser. No. 61/188,947 which was filed Aug. 13, 2008, entitled Metallized Barrier Film and Coating Therefor, and U.S. Provisional Patent App. Ser. No. 61/268,469 which was filed Jun. 12, 2009, entitled Metallized Barrier Film and Coating Therefor, the entire disclosure of both of which is incorporated herein by reference.

### BACKGROUND OF THE DISCLOSURE

1. Field of the Disclosure

The disclosure relates in general to protective films, substrates and covers, and more particularly, to a metallized barrier material having improved moisture barrier properties. Specifically, the metallized barrier material includes at least one coating that is applied to the underlying metallized substrate which precludes degradation of the underlying metallized layer and, in turn, the moisture barrier properties thereof. The metallized barrier material can then be utilized as a packaging material (alone or upon application thereof to another substrate material), or as a protective covering or wrap (where moisture barrier properties are significant).

2. Background Art

The use of various metal films and metal foils is well known in the art. In particular, such materials are often necessary in food grade application as barriers for moisture, or as moisture vapor barriers for applications such as concrete covers utilized during the curing of concrete.

For many food grade applications, aluminum foils are laminated or otherwise adhered to another substrate such as a cellulosic or a polymer base film or substrate. Problematically, the aluminum foil is rather expensive and relatively heavy. Additionally, aluminum foil when combined with substrates in packaging renders the package difficult to recycle, and compromises biodegradability.

It would be advantageous from both a cost and weight standpoint if the aluminum foils in such applications were replaced by polymer based films having metallized coatings, or direct metallization on a paperboard (i.e., cellulosic material). Such a replacement is not without problems. In particular, the metallized coatings often fail (oxidize or are otherwise compromised), especially in high humidity applications. For example, with the underlying metallized film of the present invention, coatings made from FP-3122ND from Cork (styrene-acrylic resin with MW of 766,000 and acid value of 63 and Tg of 29 deg C.) do not provide adequate barrier protection. While coatings can be applied to the metallized layer, it has been difficult to formulate a coating which can adequately protect the metallized layer in such high humidity applications.

For certain non-food applications, a metallized layer of aluminum (or other material) is deposited on a substrate, such as a polymer film. Even in a short span of hours, the unprotected metal oxidizes thereby rendering the metallized layer largely ineffective. It would be advantageous if the oxidation of the metallized layer was retarded so that the effectiveness of the cover from the standpoint of moisture vapor transmission could be extended.

Thus, it is an object of the present invention to provide a coated metallized polymer base film, or cellulosic substrate, that exhibits superior performance in high humidity applications for use in packaging and covering applications.

It is another object of the present invention to provide a coated metallized polymer base film, or cellulosic substrate, that can replace laminated aluminum foil structures in many applications.

These objects as well as other objects of the present invention will become apparent in light of the present specification, claims, and drawings.

### SUMMARY OF THE DISCLOSURE

The disclosure is directed to a metallized barrier material. The metallized barrier material can be utilized for forming packaging or protective covers wherein moisture barrier properties are necessary.

More specifically, in the present disclosure, a metallized barrier film is disclosed that includes a base material, a metallized layer and a protective coating. The base material has a first surface and a second surface. The metallized layer is vapor deposited on the first surface of the base material to a desired optical density. The protective coating is applied to the metallized layer. The protective coating comprises a butyl methacrylate or a combination of an epoxy component and an acrylic component wherein the epoxy component has an EEW of less than 800.

In a preferred embodiment, the base material comprises a cellulosic based material or a biopolymer. In such an embodiment, a second protective coating is applied to the first surface of the base material between the first surface of the base material and the metallized layer. The second protective coating can be applied in a single layer, or in two layers, wherein the first layer seals the cellulosic based material and the second layer reduces the surface roughness.

In certain embodiments, the biopolymer comprises PLA, PHA, thermoplastic starch and blends thereof.

In some such embodiments, a third protective coating is applied to the second surface of the base material.

In yet another embodiment, the base material comprises one of the group consisting of: PET, OPP, PE and blends thereof.

In another embodiment, the epoxy component has an EEW of less than 600.

In yet another embodiment, the butyl methacrylate comprises one of the group consisting of a normal, iso and copolymer butyl methacrylate.

Preferably, the acrylic component of the combination acrylic and epoxy protective coating comprises one of a butyl methacrylate, methyl methacrylate or an acrylic copolymer and the epoxy component of the combination acrylic and epoxy protective coating comprises a bisphenol A epoxy.

In other embodiments, the acrylic component of the combination acrylic and epoxy protective coating comprises a glycidyl acrylic copolymer and the epoxy component of the combination acrylic and epoxy protective coating comprises a Tris(4-hydroxyphenyl)methane triglycidyl ether.

Preferably, the optical density of the metallized layer comprises 2.5 to 3.5.

In another aspect of the invention, the invention comprises a method of making a metallized barrier material comprising the steps of: providing a base material having a first surface and a second surface; vapor depositing a metallized layer on the first surface of the base material, to a desired optical density; formulating, in a solvent, a protective coating comprising one a butyl methacrylate or a combination of an epoxy component and an acrylic component wherein the epoxy component has an EEW of less than 800; applying the protective coating in a solvent onto the metallized layer; and evaporating the solvent.

In one embodiment, the base material comprises a cellulosic based material or a biopolymer material. In such an embodiment, the method further comprises the step of applying a second protective coating to the first surface of the base material before vapor depositing the metallized layer.

In another embodiment, the step of applying a second protective coating comprises the steps of: applying a first layer of the second protective coating to the first surface of the base material before vapor depositing the metallized layer; and applying a second layer of the second protective coating to the first layer of the second protective coating before vapor depositing the metallized layer.

In one such embodiment, the method further comprises the step of applying a third protective coating to the second surface of the base material.

In yet another preferred embodiment, the method comprises the step of adhering the metallized barrier material to a second substrate. In one such embodiment, the second substrate comprises a cellulosic based material.

### BRIEF DESCRIPTION OF THE DRAWINGS

The disclosure will now be described with reference to the drawings wherein:

FIG. 1 of the drawings is a cross-sectional view of a barrier film formed in accordance with the present invention;

FIG. 2 of the drawings is a flow chart setting forth a method of manufacturing the present metallized barrier film; and

FIG. 3 of the drawings is a cross-sectional view of a barrier film formed in accordance with the present invention.

### DETAILED DESCRIPTION OF THE DISCLOSURE

While this invention is susceptible of embodiment in many different forms, there is shown in the drawings and described herein in detail a specific embodiment with the understanding that the present disclosure is to be considered as an exemplification and is not intended to be limited to the embodiment illustrated.

It will be understood that like or analogous elements and/or components, referred to herein, may be identified throughout the drawings by like reference characters. In addition, it will be understood that the drawings are merely schematic representations of the invention, and some of the components may have been distorted from actual scale for purposes of pictorial clarity.

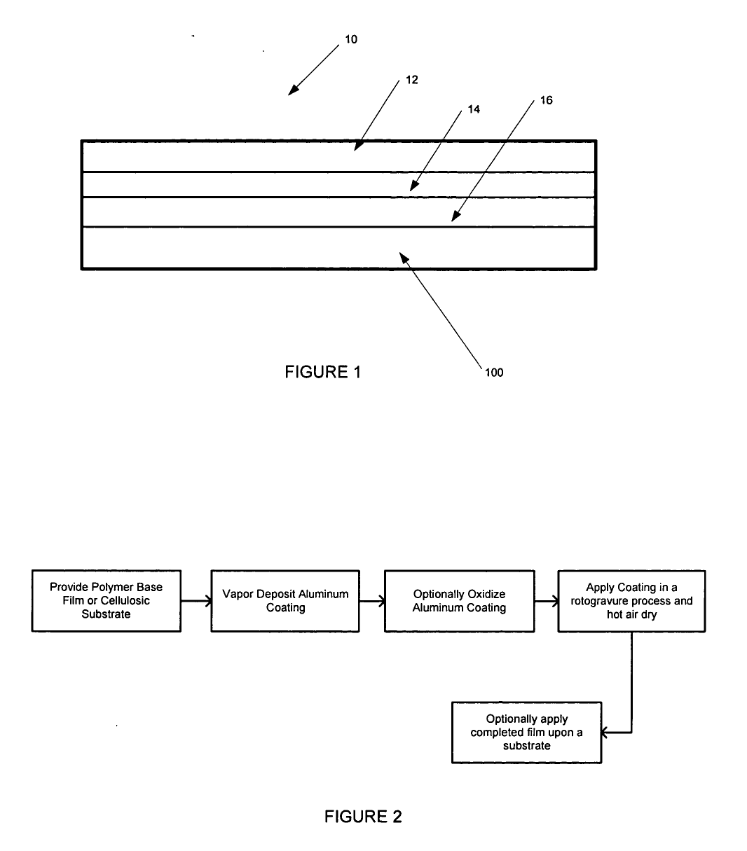

Referring now to the drawings and in particular to FIG. 1, a metallized barrier material is shown in FIG. 1 at 10. The metallized barrier material includes base material 12, metallized layer 14 and protective coating 16. The metallized barrier material can be utilized in association with packaging applications, wherein it can maintain the low initial barrier properties for extended periods of time even when exposed to high humidity atmospheric conditions. For example, the resulting barrier material can be used alone to form containers, bags, boxes or covers. In certain applications, it can be further coupled (adhered, laminated, etc) to an inner and/or outer surface of paper or boardstock 100. The paperboard is typically suitable for packaging applications where a moisture barrier is needed. In other applications, the film can be coated with a polymer (such as PE instead of being laminated to paperboard).

Wherein the base material comprises a polymer based film, the polymer base film may comprise any number of polymer films (typically a coextrusion or a lamination of a number of different polymers). One particularly suitable film is available from Vacumet under the name of Barrier-Met films, including, but not limited to Ultra Barrier-Met films. Of course, the polymer films are not limited to the particularly identified polymer film and a number of different films are likewise contemplated for use. Typically, the polymer base film comprises a thickness of approximately 36 ga to 200 ga. For example, in other embodiments, the film substrates can be any number of different materials, namely, including, but not limited to, PET, OPP, PE, PLA, PHA, Thermoplastic starch, and blends of these. It appears that the foregoing, and other petroleum and bio-based polymeric films work well with the disclosed protective coating. It will be understood that PET, OPP and PE as well as other petroleum based films tend to have some barrier properties, whereas the biopolymers, such as PLA, PHA and thermoplastic starches will tend to be substantially more porous to moisture.

With respect to utilizing cellulosic substrates, a paperboard can be utilized. It will be understood that with the porosity of most cellulosic substrates (as well as the biopolymers such as PLA, PHA and thermoplastic starches), it is advantageous to apply the protective coating described below to both sides of the metallized layer, and further, in certain embodiments to both sides of the cellulosic or biopolymer substrate. Such additional coatings further improve barrier qualities of the overall metallized barrier material.

The metallized layer comprises a vapor deposited layer of aluminum upon the polymer base film or cellulosic substrate, which when exposed to air, partially oxidizes some of the aluminum into aluminum oxide. In many embodiments, the optical density of the deposited layer is approximately 2.5 to 3.5, while, a range of 1 to 4.5 is contemplated. It will be understood that other metals, including but not limited to tin and indium, among others, is likewise contemplated for use. It will be understood that an increase in the optical density decreases the moisture vapor transmission rate in a non-linear fashion. One graphical representation is shown on page 39 of the fourth edition of the Metallizing Technical Reference published by the Association of Industrial Metallizers Coaters and Laminators. Typically, the moisture vapor transmission rate of the metallized layer is compromised when the metal is oxidized by the moisture, and, in turn, loses its effectiveness.

To combat the oxidation of the metallized layer, protective coatings are provided. In the present disclosure, it has been found that a protective coating comprising an acrylic component, or an acrylic component combined with an epoxy component provide the necessary protection for the metallized layer so as to preclude barrier reduction.

It will be understood that for application purposes, the protective coatings are in a solvent based formulation. While other solvents are contemplated, the solvents may comprise ethyl acetate, methyl ethyl ketone, amongst others. Additionally, it will be understood that there may be relatively small amounts (i.e., less than approximately 10% by weight) of other ingredients, including, but not limited to surfactants, dyes, and/or anti-static agents.

With respect to the use of an acrylic component alone, it has been found that, surprisingly, certain acrylic formulations have the barrier properties suitable for use with underlying base materials that have been metallized (i.e., Vacumet Barrier-Met family of films, without limitation). It has been found that butyl methacrylates, including normal and isobutyl homo- and copolymers, are surprisingly well suited for providing protective coatings over metal deposited through vapor deposition upon the base material. Among other acrylic resins, the following butyl methacrylates have shown to provide adequate barrier properties to preclude the degradation of the metallized layer, namely normal butyl methacrylates sold by Dianal America, Inc. of Pasadena, Tex. under the resin names MB7107, BR107, BR115 and MB2588. Other acrylic resins (i.e., non butyl methacrylates), when not formulated with an epoxy, do not appear to be suitable for use as a coating for the metallized material.

With respect to acrylic components combined with epoxy components, it has been found that acrylic resins when combined with epoxy containing resins having epoxy equivalent weights (EEW) less than approximately 600 are very suitable for use, as well as epoxy containing resins having an EEW of between 600 and 800. It has been determined that epoxies having EEW's in excess of 800 do not appear to be suitable for use.

One sample coating of an epoxy and an acrylic that was prepared comprises DER 661 solid epoxy (available from Dow Chemical Co. of Midland, Mich.) of MW=450-600 gm/mol at 3 parts weight combined with 7 parts weight of either BR-87 or PB-588 (available from Dianal America, Inc. of Pasadena, Tex.) at 21% total solids in ethyl acetate. It has been found that the PB-588 formulation has improved adhesion to the aluminum/aluminum oxide metallized surfaces. In the sample coating, the solvent based formulation is applied to the roll of metallized plastic film in a rotogravure coating process and finalized with hot air drying. While a number of thicknesses are contemplated, the coating typically has a thickness of approximately 1 micron to 10 microns. Of course, this sample coating is shown for illustrative purposes and is not deemed limiting, as other coatings in similar product families are contemplated for use. Other combinations that provided adequate barrier protection comprise those shown below in the examples, as well as, a glycidyl acrylic copolymer available from Dianal America, Inc. of Pasadena, Tex. under the resin name MB7301 combined with a tetraphenylolethane triglycidyl ether available from Hexion Specialty Chemicals, Inc. of Columbus, Ohio under the resin name Epon 1031. Additionally, while other formulations are contemplated, it has been found that the epoxy to acrylic ratio can be between 1:9 and 1:1 for the epoxy and acrylic formulations.

One method of forming the metallized barrier film is shown in FIG. 2. Specifically, in a first embodiment of the method, a polymer based film is provided. The film is placed into a vacuum chamber. Next aluminum is vapor deposited upon the polymer base film. When the metallized polymer base film is exposed to oxygen, as when the chamber is opened and the aluminum comes into contact with air, some of the aluminum layer is oxidized to form aluminum oxide. Next, the metallized polymer base film is coated with a solvent based protective coating formulation as explained above. The coating can be applied using a rotogravure coating process (while other processes are contemplated, such as reverse roll, slot die, curtain, extrusion, among others). Finally, the solvent/coating solution is hot air dried or otherwise dried to remove the solvent.

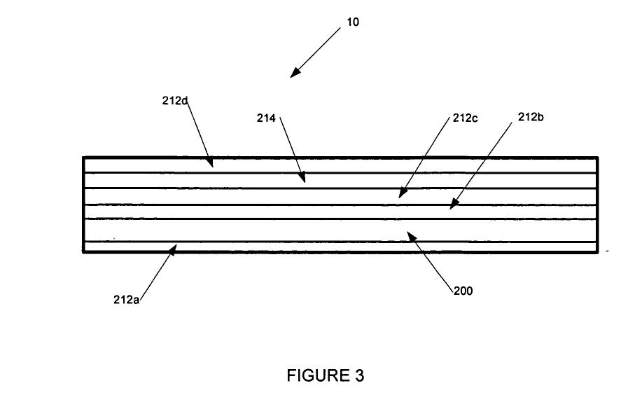

In another embodiment, shown in FIG. 3, a cellulosic or biopolymer substrate 200, instead of a barrier polymer film, is provided. The substrate (which may comprise a paperboard or other cellulosic material, or a biopolymer such as PLA, PHA and thermoplastic starches) may be coated with protective coating on both the top side 212a and the bottom side 212b. Prior to metallization of the top side of the substrate, a second coating is typically applied to the top surface 212c. The first coating tends to seal the top side of the substrate. The second coating provides a smooth surface upon which to deposit the aluminum through, for example, vapor deposition. It will be understood that in certain embodiments, the coating may be eliminated from the bottom side of the substrate. In still other embodiments, a single coating may be applied to the paperboard substrate, or such a coating may be eliminated altogether. The coatings utilized comprise the coatings that have been described above.

Once the coatings have been applied, aluminum is vapor deposited on the coated substrate to form the metallized layer 214. Finally, another protective coating 212d is applied to the surface of the deposited aluminum. The resulting structure is shown in FIG. 3. The foregoing construction has advantages over aluminum foil which is typically used in applications wherein the above construction can be utilized.

A number of different protective coating formulations were formulated and tested in substantially identical samples in substantially identical environmental conditions. The examples 1 through 4 were formulated in accordance with the disclosure above. The example 5 comprises an epoxy formulation (i.e., with no acrylic component). Examples 6 and 7 comprise the incorporation of epoxy resin into an acrylic backbone using glycidyl metharylate with no additional epoxy component. Each of the formulations were formed in a solvent. The formulations were then applied to a substrate, in a 1 to 10 micron layer. The substrate for each of the examples comprises a metallized PET material with an optical density of 2.7 which is commercially available from Vacumet, Inc. of Addison, Ill. under the name Ultra Barrier-Met film.

Each example was then placed in a controlled environment for up to 50 hours at 37.8° C., 90-100% RH. Measurements were taken every hour, for most examples, to obtain the moisture vapor transmission rate (MVTR) in grams/100 in². After each example is explained, a table of results for the formulations over a 50 hour test is provided.

### Example 1

In a first example, a butyl methacrylate was formulated. In particular, a formulation of normal butyl methacrylate (n-BMA) commercially available from Dianal America, Inc. of Pasadena, Tex. under the resin name MB7017 was prepared. It was applied (with a solvent) upon the substrate identified above. With reference to the table below, even after 50 hours, the moisture vapor transmission rate was at approximately 0.0319.

### Example 2

In a second example, an acrylic was combined with an epoxy. In particular, a formulation of methyl methacrylate (MMA) commercially available from Dianal America, Inc. of Pasadena, Tex. under the resin name BR87 was combined with a bisphenol A epoxy available from Dow Chemical Co. of Midland, Mich. under the resin name DER 661. The preparation was made in a ratio of 7:3 by weight of acrylic to epoxy. DER 661 has an EEW of between 500 and 560. It was applied (with a solvent) upon the substrate identified above. With reference to the table below, even after 50 hours, the moisture vapor transmission rate was at approximately 0.0366.

### Example 3

In a third example, butyl methacrylate and a surfactant was provided. In particular, a formulation of n-BMA commercially available from Dianal America, Inc. of Pasadena, Tex. under the resin name MB7017 was combined with a surfactant (which, in this embodiment comprised Lodyne P-208E available from Ciba Corporation of Tarrytown, N.Y., at 3.0% by weight. It was applied (with a solvent) upon the substrate identified above. With reference to the table below, even after 50 hours, the moisture vapor transmission rate was at approximately 0.0776.

### Example 4

In a fourth example, an acrylic was combined with an epoxy. In particular, a formulation of glycidyl acrylic copolymer available from Dianal America, Inc. of Pasadena, Tex. under the resin name MB7301 was combined with Tris(4-hydroxyphenyl)methane triglycidyl ether available from Sigma-Aldrich Company of St. Louis, Mo. under the resin name 413305 or Tris epoxy. The preparation was made in a ratio of 7:3 by weight of acrylic to epoxy. The 413305 epoxy has an EEW of 153. The MB7301, has an acrylic backbone with some epoxy groups, and an EEW of 142. It was applied (with a solvent) upon the substrate identified above. With reference to the table below, even after 48 hours, the moisture vapor transmission rate was at approximately 0.0511.

### Example 5

In a fifth example, an epoxy formulation was applied. In particular, a formulation of tetraphenylolethane triglycidyl ether available from Hexion Specialty Chemicals, Inc. of Columbus, Ohio under the resin name Epon 1031 was applied (with a solvent) upon the substrate. With reference to the table below, after only 31 hours, the moisture vapor transmission rate was over 1.0. Additionally, in less than 25 hours the moisture vapor transmission rate was beyond 0.5.

### Examples 6 and 7

In a sixth and seventh example, an epoxy formulation was applied. In particular, for each example a formulation of glycidyl acrylic copolymer available from Dianal America, Inc. of Pasadena, Tex. under the resin name TB120 was applied (with a solvent) upon the substrate. TB120 has an EEW of approximately 1500. With reference to the table below, within 41 hours, the moisture vapor transmission rate was over 1.0. Additionally, in less than 22 hours, the moisture vapor transmission rate was over 0.5.

| Time, | | | | | | | |
|---|---|---|---|---|---|---|---|
| hrs | Ex. 1 | Ex. 2 | Ex. 3 | Ex. 4 | Ex. 5 | Ex. 6 | Ex. 7 |
| 1 | 0.0167 | 0.0158 | 0.0266 | 0.0259 | 0.0137 | 0.0099 | 0.0193 |
| 3 | 0.0288 | 0.0193 | 0.0265 | 0.038 | 0.0158 | 0.0166 | 0.0275 |
| 7 | 0.0357 | 0.0177 | 0.0313 | 0.0391 | 0.0158 | 0.0264 | 0.059 |
| 10 | 0.0422 | 0.0178 | 0.0291 | 0.0359 | 0.0192 | 0.0743 | 0.2454 |
| 14 | 0.0412 | 0.0177 | 0.0276 | 0.0379 | 0.023 | 0.2052 | 0.4878 |
| 17 | 0.0402 | no data | 0.0318 | 0.0394 | 0.0229 | 0.3698 | 0.6501 |
| 21 | no data | 0.0335 | 0.0355 | 0.0369 | no data | 0.4994 | 0.7513 |
| 22 | 0.0379 | 0.0306 | 0.031 | 0.0422 | 0.0461 | 0.6021 | 0.8646 |
| 25 | 0.0374 | 0.0344 | 0.0335 | 0.0418 | 0.5445 | 0.6983 | 0.9794 |
| 28 | 0.0432 | 0.0304 | 0.0371 | 0.0443 | 0.8989 | 0.7879 | 1.089 |
| 31 | 0.0379 | 0.0319 | 0.0408 | 0.0442 | 1.065 | 0.8681 | 1.158 |
| 34 | 0.0418 | 0.0325 | 0.0446 | 0.0471 | 1.186 | 0.9192 | 1.219 |
| 38 | 0.0381 | 0.0363 | 0.0487 | 0.0476 | 1.261 | 0.9185 | 1.211 |
| 41 | no data | 0.0324 | 0.0551 | 0.0484 | no data | 1.034 | 1.34 |
| 42 | 0.0342 | 0.0366 | 0.0557 | 0.0469 | 1.359 | 1.065 | 1.369 |
| 43 | 0.0326 | no data | no data | no data | no data | no data | no data |
| 44 | 0.0347 | 0.0357 | no data | no data | no data | no data | no data |
| 45 | 0.0320 | no data | 0.0659 | 0.0475 | 1.426 | 1.117 | 1.425 |
| 46 | 0.0339 | no data | no data | no data | no data | no data | no data |
| 48 | 0.0336 | 0.0355 | 0.0689 | 0.0511 | 1.522 | 1.155 | 1.451 |
| 50 | 0.0329 | no data | no data | no data | 1.574 | no data | no data |
| 51 | 0.0319 | 0.0366 | 0.0776 | no data | 1.6530 | 1.2 | 1.462 |

As can be seen from a review of the data above, the first four examples, which were prepared in accordance with the disclosure identified above, after 48 hours, had moisture vapor transmission rates of below 0.1, and in some instances below 0.05. In contrast, the two samples of acrylic resins incorporating epoxy components without the acrylic component and the sample with the epoxy component without the acrylic component showed moisture vapor transmission rates in excess of 1.0 after 48 hours, and in certain circumstances in excess of 1.5. Thus, the examples made without the acrylic and epoxy component had a moisture vapor transmission rate which was in excess of ten times greater than the examples made in accordance with the present disclosure.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. A metallized barrier material comprising:
a base material having a first surface and a second surface;
a metallized layer vapor deposited on the first surface of the base material to a desired optical density;
a protective coating applied to the metallized layer, wherein the protective coating comprises a butyl methacrylate or a combination of an epoxy component and an acrylic component wherein the epoxy component has an EEW of less than 800.

2. The metallized barrier material of claim 1 wherein the base material comprises one of a cellulosic based material or a biopolymer, a second protective coating applied to the first surface of the base material between the first surface of the base material and the metallized layer, in at least one layer.

3. The metallized barrier material of claim 2 further comprising a third protective coating applied to the second surface of the base material.

4. The metallized barrier material of claim 2 wherein the biopolymer comprises one of the group consisting of PLA, PHA, thermoplastic starch, and blends thereof.

5. The metallized barrier material of claim 2 wherein the butyl methacrylate comprises one of the group consisting of a normal, iso and copolymer butyl methacrylate.

6. The metallized barrier material of claim 2 wherein the acrylic component of the combination acrylic and epoxy protective coating comprises one of a butyl methacrylate, methyl methacrylate or an acrylic copolymer and the epoxy component of the combination acrylic and epoxy protective coating comprises a bisphenol A epoxy.

7. The metallized barrier material of claim 2 wherein the acrylic component of the combination acrylic and epoxy protective coating comprises a glycidyl acrylic copolymer and the epoxy component of the combination acrylic and epoxy protective coating comprises a Tris(4-hydroxyphenyl)methane triglycidyl ether.

8. The metallized barrier material of claim 2 wherein the optical density of the metallized layer comprises 2.5 to 3.5.

9. The metallized barrier material of claim 1 wherein the base material comprises one of the group consisting of: PET, OPP, PE and blends thereof.

10. The metallized barrier material of claim 1 wherein the epoxy component has an EEW of less than 600.

11. The metallized barrier material of claim 1 wherein the butyl methacrylate comprises one of the group consisting of a normal, iso and copolymer butyl methacrylate.

12. The metallized barrier material of claim 1 wherein the acrylic component of the combination acrylic and epoxy protective coating comprises one of a butyl methacrylate, methyl methacrylate or an acrylic copolymer and the epoxy component of the combination acrylic and epoxy protective coating comprises a bisphenol A epoxy.

13. The metallized barrier material of claim 1 wherein the acrylic component of the combination acrylic and epoxy protective coating comprises a glycidyl acrylic copolymer and the epoxy component of the combination acrylic and epoxy protective coating comprises a Tris(4-hydroxyphenyl)methane triglycidyl ether.

14. The metallized barrier material of claim 1 wherein the desired optical density of the metallized layer comprises 2.5 to 3.5.

15. A method of making a metallized barrier material comprising the steps of:
providing a base material having a first surface and a second surface;
vapor depositing a metallized layer on the first surface of the base material, to a desired optical density;
formulating, in a solvent, a protective coating comprising a butyl methacrylate or a combination of an epoxy component and an acrylic component wherein the epoxy component has an EEW of less than 800;
applying the protective coating in a solvent onto the metallized layer; and
evaporating the solvent.

16. The method of claim 15 wherein the base material comprises one of a cellulosic based material or biopolymer, the method further comprising the step of:
applying a second protective coating to the first surface of the base material before vapor depositing the metallized layer.

17. The method of claim 16 wherein the step of applying a second protective coating comprises the steps of:
applying a first layer of the second protective coating to the first surface of the base material before vapor depositing the metallized layer; and
applying a second layer of the second protective coating to the first layer of the second protective coating before vapor depositing the metallized layer.

18. The method of claim 16 further comprising the step of applying a third protective coating to the second surface of the base material.

19. The method of claim 15 further comprising the step of:
adhering the metallized barrier material to a second substrate.

20. The method of claim 19 wherein the second substrate comprises a cellulosic based material.
